(19) United States
(12) Patent Application Publication
(10) Pub. No.: US 2012/0147565 A1
(43) Pub. Date: Jun. 14, 2012

(54) HEAT DISSIPATION AND TEMPERATURE-HOMOGENIZING STRUCTURE AND ELECTRONIC DEVICE HAVING THE SAME

(75) Inventors: Ya-Tung I, Taipei County (TW); Wen-Chi Chen, Taipei (TW); Chien-Chung Hsu, Taipei County (TW); Yi-Jen Lu, Yilan County (TW); Pao-Hsiu Fan, Taipei County (TW)

(73) Assignees: LITE-ON TECHNOLOGY CORPORATION, Taipei (TW); SILITEK ELECTRONIC (GZ) CO., LTD., Guangzhou (CN)

(21) Appl. No.: 13/312,297

(22) Filed: Dec. 6, 2011

(30) Foreign Application Priority Data
Dec. 10, 2010 (CN) 201010596957.9

(51) Int. Cl. H05K 7/20; F28F 7/00

(52) U.S. Cl. 361/720; 165/185

(57) ABSTRACT

A heat dissipation and temperature-homogenizing structure which includes a body made of a material with low thermal conductivity and a heat conducting member made of a material with high thermal conductivity is disclosed. The body has opposite inner surfaces and outer surfaces. The heat conducting member is embedded inside the body and is completely surrounded between the inner surfaces and the outer surfaces. When the electronic device generates heat, the heat is firstly transferred to the heat conducting member from the inner surfaces, and then rapidly and evenly spreads over the heat conducting member. Finally, the heat inside the heat conducting member is uniformly dissipated through the outer surfaces. Accordingly, the heat dissipation and temperature-homogenizing structure may effectively and evenly spread the heat over the outer surfaces for exchanging heat with the ambient.

### CROSS-REFERENCE TO RELATED APPLICATIONS

This non-provisional application claims priority under 35 U.S.C. §119(a) on Patent Application No(s). 201010596957.9 filed in China, P.R.C. on Dec. 10, 2010, the entire contents of which are hereby incorporated by reference.

### BACKGROUND OF THE INVENTION

1. Field of Invention

The present invention relates to a heat dissipation structure, and in particular to a heat dissipation and temperature-homogenizing structure having a heat conducting member embedded therein for homogenizing the temperature distribution of an electronic device, which is suitable for uniformly dissipating heat generated from electronic components to the housing of the electronic device.

2. Related Art

Adapters and power supplies are indispensable electronic devices for powering various electrical appliances or information products. Besides, it is also well known that there are many electronic components, including high-heat-generating elements (e.g. transformer, MOSFET, diodes, inductors etc.) and low-heat-generating elements (e.g. capacitors or resistors), mounted on a circuit board inside the electronic device. Accordingly, when the electronic device is in operation, the above electronic components may respectively generate heats with different powers. If the heat cannot be effectively transferred to the surrounding or dissipated by suitable means, the excessive heat or the locally elevated temperature (i.e. hot spot) might result in the failure of the electronic components, and then cause the breakdown of the whole electronic device. Furthermore, the locally elevated temperature on the external surface of the housing of the electronic device leads to some safety problems.

For example, the adapter is used to rectify currents from an external AC power source and convert the AC power to DC power that the electrical appliance, e.g. a portable computer can use, or to recharge the battery of the electrical appliance. However, with trend towards the integration of the integrated circuit, the adapter becomes compact, resulting in the heat dissipation problem caused by the miniaturized adapter aggravated. Furthermore, since the high-heat-generating elements are disposed at very short distances between each other, the temperature of some local regions of the adapter may be extremely high. The extremely high temperature on the external surface of the housing of the adapter may make users feel uncomfortable.

In addition, the conventional housing of the adapter made of plastic cannot transfer heat easily, and thus the heat cannot be effectively dissipated and, therefore, can easily cause the problem of the hot spot of the housing. Such hot spot will result in the problems mentioned above.

The conventional method for dissipating heat is implemented by disposing an additional heat sink (e.g. copper foil or boron nitride) on the inner side of the housing of the high power electronic device, so as to reduce the locally elevated temperature on the external surface of the housing. However, the heat dissipation effect provided by such heat sink is limited and the electrical insulation between the heat sink and the electronic components of the electronic device must be considered. In addition, the processes are quite complicated, which causes the increase of the labor cost. Furthermore, such method fails to effectively reduce and homogenize locally elevated temperature on the external surface of the housing.

Therefore, it is the problem in urgent need of how to provide a heat dissipation and temperature-homogenizing structure capable of rapidly and uniformly dissipating the heat generated by the electronic device in operation.

### SUMMARY OF THE INVENTION

To solve the above problems, the present invention provides a heat dissipation and temperature-homogenizing structure for homogenizing the temperature distribution of an electronic device, which is suitable for uniformly dissipating heat generated from electronic components to the housing of the electronic device, thereby solving the problem of hot spot of the housing caused by the concentration of heat sources of the heat-generating elements inside the electronic device in the prior art.

In order to achieve the above objectives, the present disclosure is to provide a heat dissipation and temperature-homogenizing structure for an electronic device. The electronic device comprises a circuit board configured to support a plurality of electronic components, and the electronic components comprise high-heat-generating elements and low-heat-generating elements.

The heat dissipation and temperature-homogenizing structure of the present invention comprises a body and a heat conducting member. The body is made of low thermal conductivity materials. The body is a hollow housing which comprises side walls that define an upper casing and a lower casing. The body has opposite inner and outer surfaces, and the inner surfaces of the side walls of the body are defining an accommodating space therein for accommodating the circuit board. The heat conducting member is made of high thermal conductivity materials. The heat conducting member is embedded inside the body, and the heat conducting member is completely surrounded between the inner surfaces and the outer surfaces of the side walls of the body.

According to one embodiment of the present disclosure, at least one hole is formed on the inner surface nearest to the circuit board and exposes a part of the heat conducting member and the heat conducting member is electrically connected to the circuit board via the hole.

Since the heat conducting member is embedded in the body of the heat dissipation and temperature-homogenizing structure, and the heat conducting member is completely surrounded between the inner surfaces and the outer surfaces of the side walls of the body, so that the heat generated by the electronic components may firstly be transferred to the heat conducting member through the inner surfaces and spread over all the side walls of the body through the heat conducting member, and then the heat is dissipated through the outer surfaces of the body. In this way, the heat can be uniformly dissipated.

In addition, since the heat dissipation and temperature-homogenizing structure has the function of electrical insulation, the failure of the electronic device under the Hi-Pot test is prevented without adding any additional insulating element. In other words, there is no need of the insulating element for passing the Hi-Pot test, and therefore, fabricating cost is reduced.

Furthermore, since the heat conducting member is embedded in the body by injection molding or other method, such as using adhesive, to form as a unitary body, the structural strength of the electronic device is enhanced.

Several exemplary embodiments accompanied with figures are described in detail below to further describe the disclosure in details.

### BRIEF DESCRIPTION OF THE DRAWINGS

The present invention will become more fully understood from the detailed description given herein below for illustration only, and thus are not limitative of the present invention, and wherein:

FIG. 1 is an exploded view of an electronic device having a heat dissipation and temperature-homogenizing structure according to a first embodiment of the present invention;

FIG. 2 is a cross-section view of an electronic device having a heat dissipation and temperature-homogenizing structure according to the first embodiment of the present invention;

FIG. 3 is a schematic view of a heat conduction path of an upper casing according to an embodiment of the present invention;

FIG. 4 is an exploded view of an electronic device having a heat dissipation and temperature-homogenizing structure according to a second embodiment of the present invention;

FIG. 5 is a cross-section view of an electronic device having a heat dissipation and temperature-homogenizing structure according to the second embodiment of the present invention;

FIG. 6A is a schematic three-dimensional view of an electronic device having a heat dissipation and temperature-homogenizing structure according to an embodiment of the present invention;

FIG. 6B is a graph of temperature variation data of the heat dissipation and temperature-homogenizing structure in FIG. 6A with a heat conducting member of 0.5 mm in thickness embedded inside; and

FIG. 7 is a cross-section view of an electronic device having a heat dissipation and temperature-homogenizing structure according to a third embodiment of the present invention.

### DETAILED DESCRIPTION OF THE INVENTION

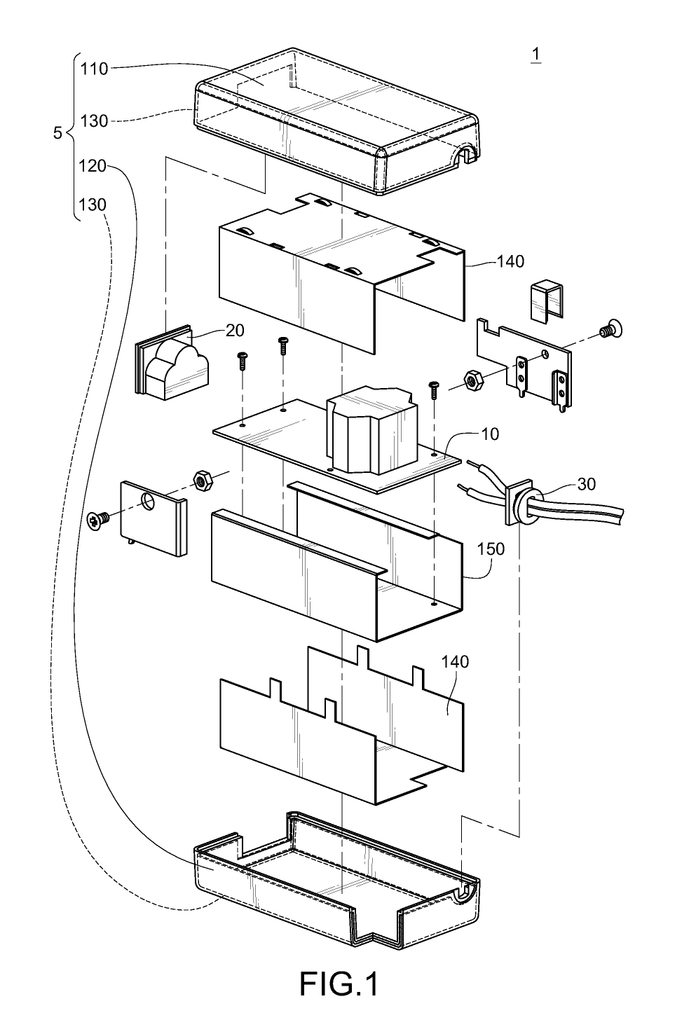

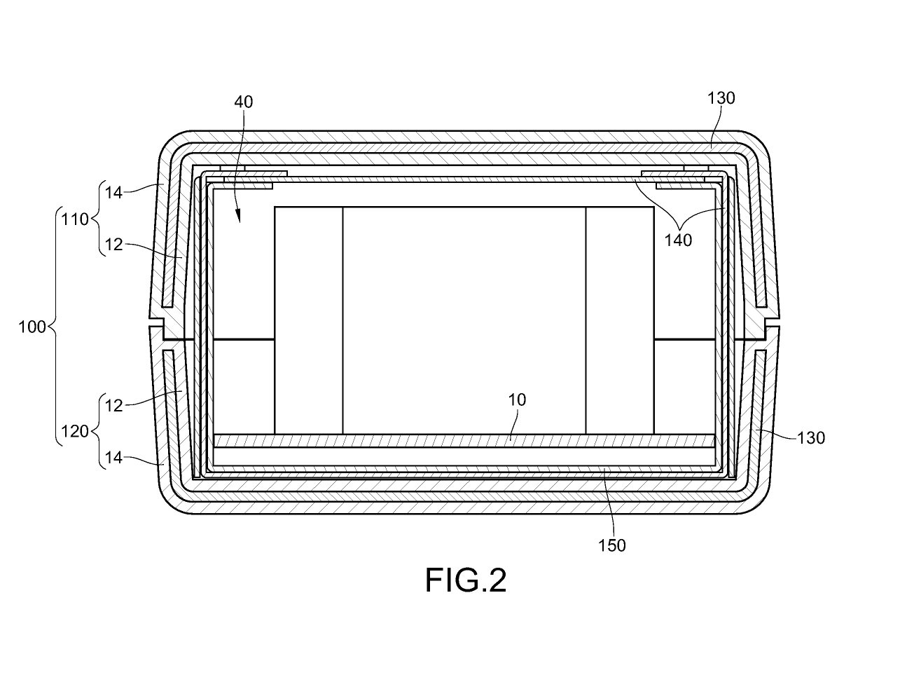

FIG. 1 and FIG. 2 are an exploded view and a cross-section view of an electronic device having a heat dissipation and temperature-homogenizing structure according to a first embodiment of the present invention, respectively. In this embodiment, the electronic device 1 is an adapter. However, the embodiment is not intended to limit the type of the electronic device 1. In some embodiments, for example, the electronic device 1 may be a power supply or a transformer.

Referring to FIG. 1, the electronic device 1 comprises a heat dissipation and temperature-homogenizing structure 5, a circuit board 10, an input element 20 (or referred to as a primary side) and an output element 30 (or referred to as a secondary side). In the present invention, the input element 20 may be a plug, a socket or a power cable, and the output element 30 may be a socket, a plug or a power cable according to the input element 20. For convenience of illustration only, in the following embodiment, for example, the input element 20 is a socket from which a plug may get alternating current, and the output element 30 is a power cable through which an electronic equipment, e.g. portable computer, may be electrically connected.

A plurality of electronic components are disposed on and electrically connected to the circuit board 10. The electronic components may comprise high-heat-generating elements and low-heat-generating elements (not shown), and may be, but is not limited to, transformers, MOSFETs (metal oxide semiconductor field effect transistors), diodes, capacitors, resistors, inductors, another passive elements, or the combination thereof. When the circuit board 10 is powered through the input element 20, heat is generated by the electronic components which are powered by the circuit board 10 in operation.

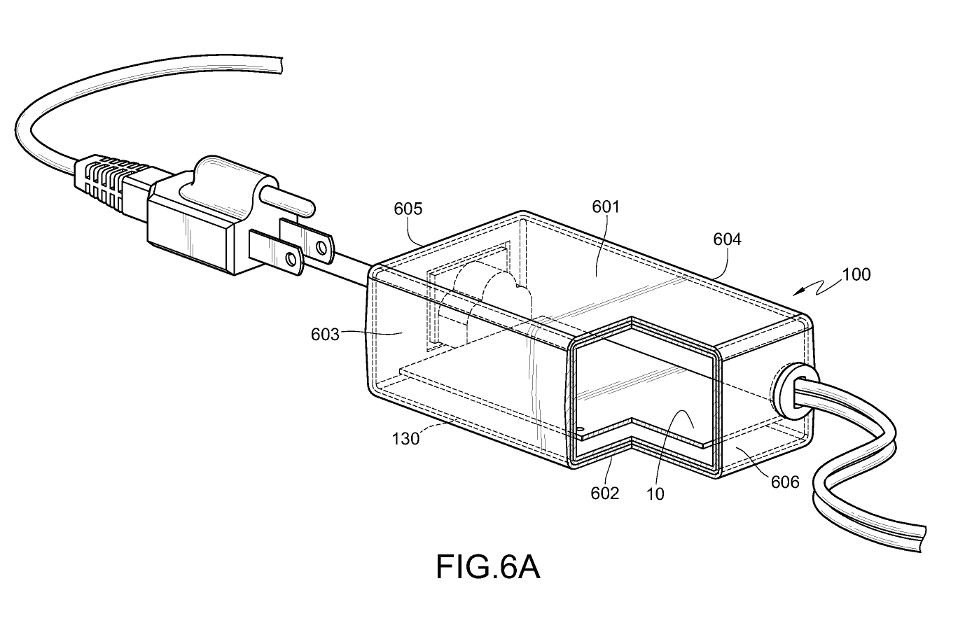

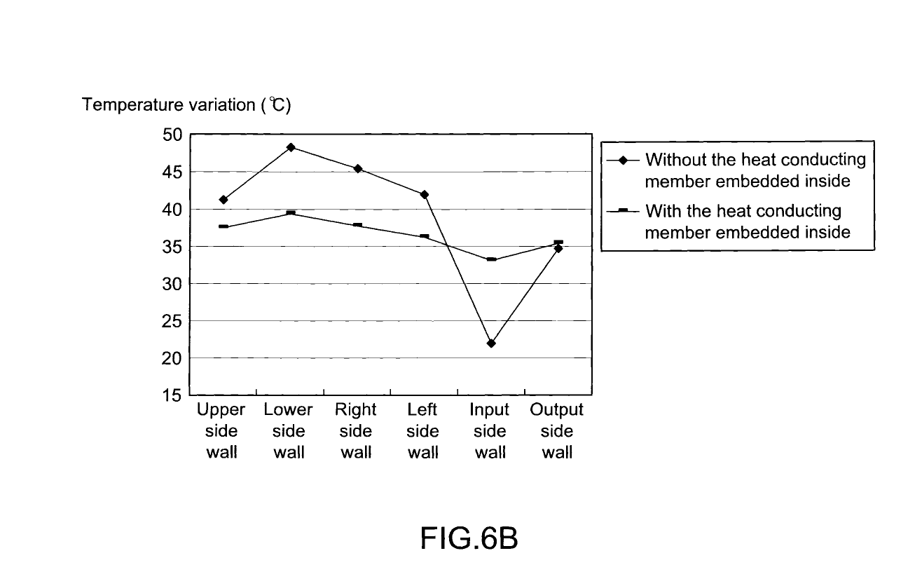

The heat dissipation and temperature-homogenizing structure 5 of the electronic device 1 according to the first embodiment of the present invention, comprises a heat conducting member 130 and a body 100 made of insulating materials with low thermal conductivity, such as plastics. Please refer to FIG. 6A, which is a schematic three-dimensional view of the electronic device 1 having the heat dissipation and temperature-homogenizing structure 5 according to an embodiment of the present invention. The body 100 comprises an upper side wall 601, a lower side wall 602, a left side wall 603, a right side wall 604, an input side wall 605 connected to the input element 20 and an output side wall 606 connected to the output element 30 that define an upper casing 110 and a lower casing 120 detachably connected to the upper casing 110. Besides, the body has opposite inner and outer surfaces 12, 14, and the inner surfaces 12 of the side walls 601-606 of the body 100 defines an accommodating space 40 therein. The circuit board 10 is accommodated in the accommodating space 40 and is completely enclosed by the side walls 601-606 of the body 100. The inner surfaces 12 are defined as sides of the body 100 facing and adjacent to the circuit board 10, and the outer surfaces 14 are defined as the other sides of the body 100 which are exposed to the ambient.

For the instant disclosure, the heat conducting member 130 is preferably made of high thermal conductivity materials, such as metal (e.g. aluminum or copper), ceramic, graphite, metal alloys, etc. The heat conducting member 130, embedded in both the upper casing 110 and the lower casing 120 of the body 100, is completely surrounded between the inner surfaces 12 and the outer surfaces 14 of the side walls 601-606 of the body 100. In other words, the heat conducting member 130 has a shape similar to that of the combination of the upper casing 110 and the lower casing 120. According to the heat dissipation and temperature-homogenizing structure 5 of the present invention, since the heat conducting member 130 is embedded in the body 100 and formed between the inner surfaces 12 and the outer surfaces 14 of the side walls 601-606 by injection molding or adhesive through additional processes for forming as a unitary body, the structural strength of the electronic device 1 housing is increased.

When heat is generated by the electronic components on the circuit board 10, the heat may be firstly transferred to the heat conducting member 130 through the inner surfaces 12, then rapidly and evenly spread over the heat conducting member 130 due to the high thermal conductivity of the heat conducting member 130, and finally the heat is dissipated to the ambient through the outer surfaces 14 via the large heat dissipation area. Accordingly, the temperature distribution of the heat dissipation and temperature-homogenizing structure 5 is homogenized, and the heat can be uniformly dissipated over a large heat dissipation area. Furthermore, to achieve the purpose of the present invention, the shape of the heat conducting member 130 may be, but is not limited to, plane, wave or another irregular shape so as to effectively increase the effective heat transfer area of the heat conducting member 130.

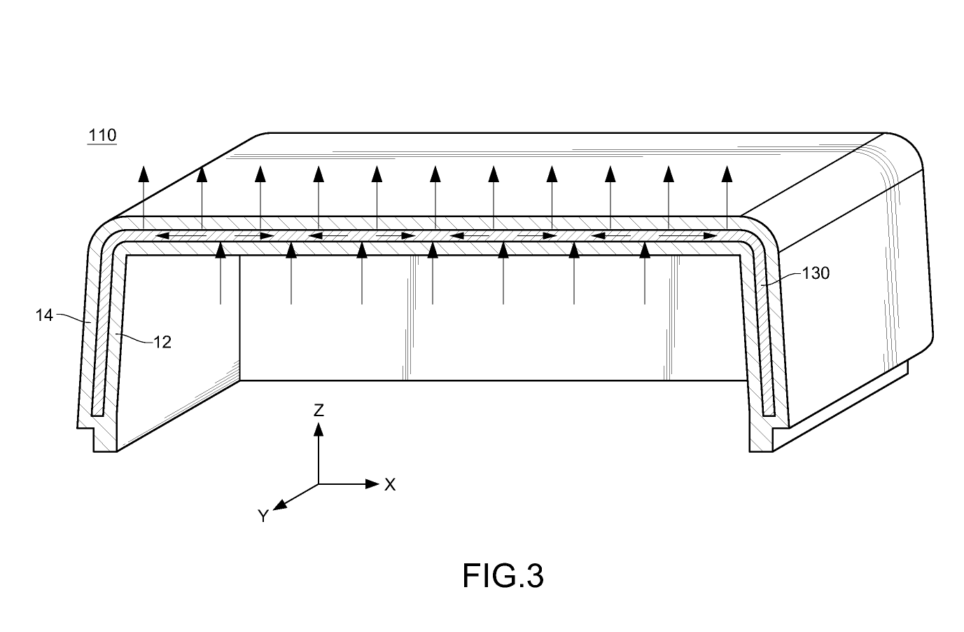

FIG. 3 is a schematic view of a heat conduction path of an upper casing 110 according to an embodiment of the present invention. The heat conduction path of the lower casing 120 is similar to that of the upper casing 110, and, therefore, only the upper casing 110 in FIG. 3 is taken as an example for illustration. However, the disclosure does not intend to limit the heat conduction path by FIG. 3.

As shown in the FIG. 3, the heat generated by the electronic components on the circuit board 10 during operation is firstly transferred to the inner surfaces 12. Since thermal conductivity of the inner surfaces 12 is low, once the heat generated by the high-heat-generating elements or low-heat-generating elements is transferred to the inner surfaces 12, the heat is slowly distributed through the inner surfaces 12 in a first direction (e.g. in the z-axis direction in the FIG. 3). Whereas the heat conducting member 130 is disposed adjacent to the inner surfaces 12 and has a higher thermal conductivity than that of the inner surfaces 12, the heat transferred from the inner surfaces 12 will be evenly and rapidly distributed throughout the heat conducting member 130 in a second direction (e.g. in the x-axis direction and y-axis direction in the FIG. 3) at a relatively higher thermal conduction rate. The large heat transfer area and high thermal conduction rate of the heat conducting member 130 enables the heat spreads out evenly, thereby effectively reducing and homogenizing locally elevated temperature of the inner surfaces 12. Then, the heat is transferred to the outer surfaces 14 from the heat conducting member 130. Since the thermal conductivity of the outer surfaces 14 is lower than that of the heat conducting member 130, the heat is slowly distributed through the outer surfaces 14 in a third direction (e.g. in the z-axis direction in FIG. 3). Because the outer surfaces 14 slows down the thermal conduction rate in the vertical direction, the heat can be uniformly distributed in the heat conducting member 130 and effectively dissipated to the ambient through the outer surfaces 14 via the large heat dissipation area.

Since the thermal conduction rates in the first/third and the second directions are considerably distinguished, the heat generated from the high-heat-generating elements or low-heat-generating elements will be homogeneously distributed by the heat conducting member 130 at first, and then transferred to the outer surfaces 14 of the body 100 for heat dissipation. In the instant disclosure, changing the thermal conduction direction (i.e. the second direction is perpendicular to both the first and the third directions) can minimize the locally elevated temperature, and thus maintain homogenous temperature distribution and dissipate the heat effectively on the outer surfaces 14 of the electronic device 1. Accordingly, the problems caused by excess heat from high heat generating power and hot spots making users feel uncomfortable can be solved. Moreover, the heat conducting member 130 is embedded in the body 100 by injection molding or other method to form as a unitary body 100, and therefore the structural strength of the electronic device 1 is enhanced.

In addition, to prevent the EMI (Electromagnetic Interference) from occurring to the electronic components, in the heat dissipation and temperature-homogenizing structure 5 according to the first embodiment of the present invention as shown in FIG. 1 and FIG. 2, the body 100 may further comprise, but is not limited to, at least one shielding cover 140 and an insulating element 150 both of which are disposed in the accommodating space 40. The shielding cover 140 is made of metal, and covers the electronic components of the circuit board 10. The insulating element 150 is disposed between the circuit board 10 and the shielding cover 140 so as to effectively insulate the electronic components on the circuit board 10. Thus, according to the heat dissipation and temperature-homogenizing structure 5 of the first embodiment, besides the homogeneous temperature distribution of the electronic device 1, the advantage of electromagnetic protection is also achieved through the shielding cover 140 and the insulating element 150.

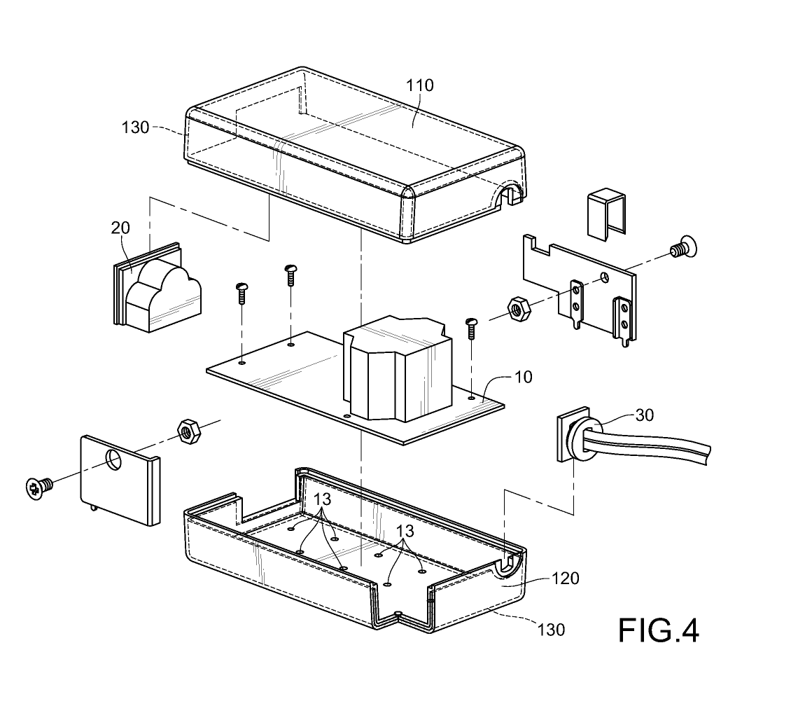

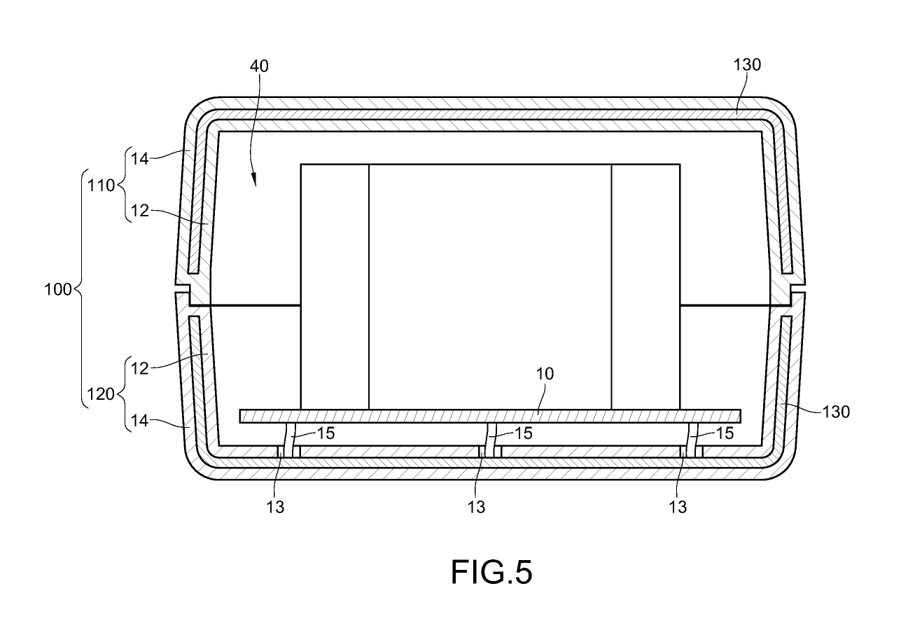

FIG. 4 and FIG. 5 are an exploded view and a cross-section view of the electronic device having the heat dissipation and temperature-homogenizing structure according to a second embodiment of the present invention, respectively. In the second embodiment, same numerals are applied to the same parts in the first embodiment, and the difference between the first and the second embodiments is the inner surface 12 nearest to the circuit board 10 has at least one hole 13 exposing a part of the heat conducting member 130. Specifically, in this embodiment, the inner surface 12 is adjacent to bottom of the circuit board 10. A ground of the circuit board 10 and the heat conducting member 130 are electrically conducted to each other by an electrically conductive member 15, such as a wire, a conductive plug or a conductive foam, passing through the hole 13. According to the second embodiment of the present invention, since the heat conducting member 130 functions as a shielding cover of the electronic components for preventing the EMI, there is no need of the shielding cover 140 of the first embodiment.

In addition, the inner surfaces 12 are made of insulating materials, such as plastic. Therefore, in the heat dissipation and temperature-homogenizing structure 5 according to the second embodiment of the present invention (as shown in FIG. 5), the primary side is prevented from being electrically connected to the secondary side of the electronic device 1 through the electrical insulation effect provided by the inner surfaces 12. Accordingly, in the second embodiment, there is in no need of additional insulating sheet or other insulating mean to electrically insulate the primary side from the second side. Therefore, the electronic device 1 is miniaturized, and failure of the electronic device 1 under the Hi-Pot test is avoided.

The first and the second embodiments of the present invention may achieve a better heat dissipation efficiency by embedding the heat conducting member 130 as shown in FIG. 6A. In details, as shown in FIG. 6A, the heat conducting member 130 of the heat dissipation and temperature-homogenizing structure 5 of the present invention has at least six sides surrounding the periphery of the circuit board 10. Therefore, the heat conducting member 130 completely surrounds the periphery of the circuit board 10 so as to maintain homogeneous temperature distribution and achieve a better heat dissipation efficiency due to an increased heat transfer area.

FIG. 6B is a graph of temperature variation data of the heat dissipation and temperature-homogenizing structure 5 in FIG. 6A with a heat conducting member of 0.5 mm in thickness embedded inside. As shown in FIG. 6B, the temperature variation of the side walls of the heat dissipation and temperature-homogenizing structure 5 having the heat conducting member 130 embedded inside is moderate and gentle as compared with the same-size conventional electronic device having an additional heat sink disposed inside. That is to say, the heat dissipation and temperature-homogenizing structure 5 of the present disclosure having the heat conducting member 130 embedded inside may homogenize the temperature distribution of the electronic device 1. Furthermore, the hottest spot temperature on the housing of the electronic device 1 is reduced by 8.8° C.

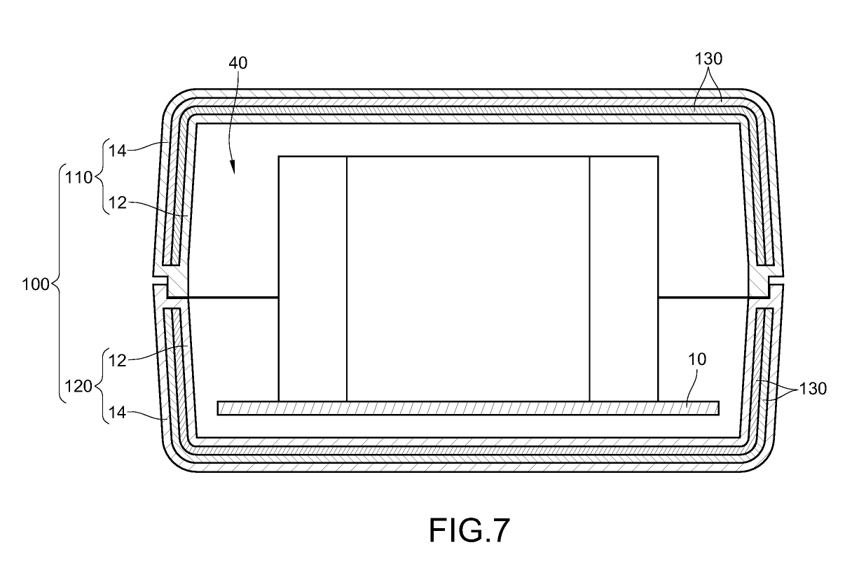

In addition, the number of the heat conducting member 130 embedded inside the heat dissipation and temperature-homogenizing structure 5 is not intended to limit the scope of the present invention. The heat conducting member 130 may be made by a single layer or multiple stacked layers having different thermal conductivities. For example, FIG. 7 is a cross-section view of a heat dissipation and temperature-homogenizing structure according to a third embodiment of the present invention. A plurality of heat conducting members 130 is stacked between the inner surfaces 12 and the outer surfaces 14 of the body 100 so as to increase the effective heat transfer area and increase the efficiency of homogenizing the temperature distribution of the electronic device 1. Moreover, the heat conducting members 130 are embedded in the body 100 by injection molding or other method, such as using adhesive, to form as a unitary body 100, and therefore the structural strength of the electronic device 1 is more enhanced.

Therefore, in view of the above, the temperature distribution of the housing of the electronic device is homogenized by embedding a heat conducting member in the body and disposing the heat conducting member to completely surround the periphery of the circuit board. Thus, the heat dissipation and temperature-homogenizing structure according to an embodiment of the present invention can be used for replacing the plastic housing of the electronic device in the prior art, so that the temperature distribution of the electronic device is homogenized, and the hot spot on the plastic housing of the electronic device is prevented.

In addition, the EMI is prevented from occurring to the electronic device due to that at least one hole is formed on at least one of the inner surfaces of the body, and that the heat conducting member embedded in the body functions as the shielding cover for the electronic components. Furthermore, the heat dissipation and temperature-homogenizing structure of the present invention has the function of electrical insulation for avoiding failure under the Hi-Pot test, and, therefore, there is no need of additional insulating members.

In addition, the heat conducting member is embedded in the body by injection molding, adhesive or other method to form as a unitary body, and therefore the structural strength of the electronic device is enhanced.

What is claimed is:

1. A heat dissipation and temperature-homogenizing structure, applicable to an electronic device comprising a circuit board and a plurality of electronic components disposed on and electrically connected to the circuit board, the heat dissipation and temperature-homogenizing structure comprising:
a body made of a material with low thermal conductivity, having side walls that define an accommodating space for accommodating the circuit board, wherein the body has opposite inner surfaces and outer surfaces; and
a heat conducting member made of a material with high thermal conductivity, embedded inside the body and completely surrounded between the inner surfaces and the outer surfaces of the side walls of the body;
wherein heat generated by the electronic components disposed on the circuit board is transferred to the heat conducting member from the inner surfaces, then conducted inside and distributed throughout the heat conducting member, and finally transferred to the outer surfaces and dissipated.

2. The heat dissipation and temperature-homogenizing structure according to claim 1, wherein the heat is transferred from the inner surfaces towards the heat conducting member in a first direction; when the heat is transferred to the heat conducting member, the heat is conducted inside and spread over the heat conducting member in a second direction; when the heat is transferred from the heat conducting member to the outer surfaces, the heat is transferred in a third direction, wherein the first direction and the third direction are both different from the second direction.

3. The heat dissipation and temperature-homogenizing structure according to claim 1, wherein the heat conducting member is completely surrounded between the inner surfaces and the outer surfaces of the body in an embedded injection molding manner to form as a unitary molded body.

4. The heat dissipation and temperature-homogenizing structure according to claim 1, wherein the heat conducting member is completely surrounded between the inner surfaces and the outer surfaces of the body by adhesive method to form as a unitary body.

5. The heat dissipation and temperature-homogenizing structure according to claim 1, wherein the body comprises an upper casing and a lower casing, attached to the upper casing and together with the upper casing enclosing the accommodating space, and the heat conducting member is embedded inside the body in a shape consistent with the combination of the upper casing and the lower casing.

6. The heat dissipation and temperature-homogenizing structure according to claim 1, wherein the material of the heat conducting member is metal, metal alloys, ceramic, graphite or material having a high thermal conductivity.

7. The heat dissipation and temperature-homogenizing structure according to claim 6, wherein the material of the heat conducting member is aluminum or copper.

8. The heat dissipation and temperature-homogenizing structure according to claim 6, wherein at least one hole is further formed on the inner surface nearest to the circuit board and exposed a part of the heat conducting member, and the heat conducting member is electrically connected to the circuit board via the hole.

9. The heat dissipation and temperature-homogenizing structure according to claim 1, wherein the body is made of electrical insulation material.

10. The heat dissipation and temperature-homogenizing structure according to claim 9, wherein the material of the body is plastic or material having a low thermal conductivity.

11. The heat dissipation and temperature-homogenizing structure according to claim 1, wherein the body further comprises a shielding cover disposed in the accommodating space, and the shielding cover covers the electronic components of the circuit board.

12. The heat dissipation and temperature-homogenizing structure according to claim 11, wherein the body further comprises an insulating element disposed in the accommodating space, and the insulating element is disposed between the circuit board and the shielding cover.

13. The heat dissipation and temperature-homogenizing structure according to claim 1, wherein the side walls of the body surround a periphery of the circuit board, and the heat conducting member is completely embedded in the side walls and completely surrounded between the inner surfaces and the outer surfaces so as to increase a heat transfer area.

14. The heat dissipation and temperature-homogenizing structure according to claim 13, wherein a shape of the heat conducting member is plane, wave or irregular shape.

15. The heat dissipation and temperature-homogenizing structure according to claim 1, wherein the heat conducting member is made by a single layer or multiple stacked layers having different thermal conductivities.

16. An electronic device, comprising:
a circuit board;
a plurality of electronic components disposed on and electrically connected to the circuit board; and
a heat dissipation and temperature-homogenizing structure comprising:
a body made of a material with low thermal conductivity, having side walls that define an accommodating space for accommodating the circuit board, wherein the body has opposite inner surfaces and outer surfaces; and
a heat conducting member made of a material with high thermal conductivity, embedded inside the body and completely surrounded between the inner surfaces and the outer surfaces of the side walls of the body;
wherein heat generated by the electronic components disposed on the circuit board is transferred to the heat conducting member from the inner surfaces, then conducted inside and distributed throughout the heat conducting member, and finally transferred to the outer surfaces and dissipated.

17. The electronic device according to claim 16, wherein the electronic device is an adaptor, a power supply or a charger.

18. The electronic device according to claim 16, wherein the heat is transferred from the inner surfaces towards the heat conducting member in a first direction; when the heat is transferred to the heat conducting member, the heat is conducted inside and spread over the heat conducting member in a second direction; when the heat is transferred from the heat conducting member to the outer surfaces, the heat is transferred in a third direction, wherein the first direction and the third direction are both different from the second direction.

19. The electronic device according to claim 16, wherein the heat conducting member is completely surrounded between the inner surfaces and the outer surfaces of the body in an embedded injection molding or adhesive manner to form as a unitary body.

20. The electronic device according to claim 16, wherein at least one hole is further formed on the inner surface nearest to the circuit board and exposed a part of the heat conducting member, and the heat conducting member is electrically connected to the circuit board via the hole.

21. The electronic device according to claim 16, wherein the heat conducting member is made by a single layer or multiple stacked layers having different thermal conductivities.
